(19) United States
(12) Patent Application Publication
(10) Pub. No.: US 2019/0154733 A1
(43) Pub. Date: May 23, 2019

(54) CURRENT DETECTION DEVICE HAVING MULTI-LAYERED PCB CORE STRUCTURE

(71) Applicant: COBONTECH CO., LTD, Cheongju-si, Chungcheongbuk-do (KR)

(72) Inventor: Yeunsook JOO, Goesan-gun, Chungcheongbuk-do (KR)

(21) Appl. No.: 16/317,928

(22) PCT Filed: Jun. 20, 2017
(86) PCT No.: PCT/KR2017/006430

§ 371 Date: Jan. 15, 2019

(30) Foreign Application Priority Data
Jul. 29, 2016 (KR) 10-2016-0096978

(51) Int. Cl. G01R 15/18; G01R 33/04; G01R 33/00

(52) U.S. Cl. CPC G01R 15/18; G01R 33/0005; G01R 33/04

(57) ABSTRACT

The present invention relates to a current detection device having a multi-layered PCB core structure, and more particularly, to a current detection device having a multi-layered PCB core structure, by which a coil of a conventional current detection device is replaceable to make electrical properties constant and mass production is possible.

### TECHNICAL FIELD

The present invention relates to a current detection device having a multi-layered PCB core structure, and more particularly, to a current detection device having a multi-layered PCB core structure, by which a coil of a conventional current detection device is replaceable to make electrical properties constant (uniform) and mass production is possible.

### BACKGROUND ART

Referring to FIG. 1, a conventional current detection device includes a load (20) that operates according to an input power source, a voltage output control unit (10) that inputs the power source from a power supply (PS) and supplies the power source to the load (20) according to an input control signal, a coil (CL) wound on a voltage-carrying copper wire (PP) for transferring a current passing through the load (20) to the power supply (PS), an induced current detection unit (40A) for detecting the current flowing in the coil (CL) and induced on the coil (CL) according to the electromagnetic induction when the current flows through the copper wire (PP), and a voltage transmission unit (40B) for changing the amount of induced current, which is outputted from the induced current detection unit (40A), into a voltage amount to provide it to the voltage output control unit (10).

The current detection system constructed as described above has an effect of solving a problem caused in the current detection system according to the voltage detection described above. However, since a coil having a specific capacity needs to be wound around a circuit, the manufacturing process is complicated. Also, since the electrical characteristics depending on the interval and direction of the coil are not constant, it causes a problem that the detection accuracy of the current detecting device is deteriorated.

On the other hand, as methods of measuring the current flowing through the wire, there are a direct measurement method in which a current measuring device is electrically connected directly to the wire so as to measure the current of the wire and an indirect measurement method in which a current measuring device detects an electromagnetic field generated around the wire so as to measure the current of the wire.

Here, the direct measurement method is complicated and difficult to connect the measuring instrument thereto. Also, since it cannot be separated from the circuit, in recent years, the indirect measurement method for avoiding the restriction of the direct measurement method has been emerged.

As a representative example of the indirect measurement method, there is a method using a flux gate method.

According to the current measuring method using the flux gate method, the alternating current is applied to two cores, so that the alternating magnetization directions are opposite to each other and the change of an electromotive force generated in coils wound on two cores is detected so as to detect a DC magnetic flux due to the current flowing in the conductive wire.

The alternating magnetic flux due to the electric current of the conductive wire is detected by using a separate coil. Thus, the electric current corresponding to the detected DC flux and alternating magnetic flux are applied to offset the electromagnetic field caused by the electric current flowing in the conductive wire, so that the current flowing through the conductive wire is measured through the detection of the applied current.

As described above, there are conventional techniques for measuring the current by the flux gate methods such as Korean registration utility model No. 20-0283971, Korean patent publication No. 10-2010-0001504, and Korean patent publication No. 10-2004-0001535 etc.

According to the conventional techniques, when two cores are magnetized in directions opposite to each other by applying the current generated by a square wave or a sinusoidal wave, the distortion generated in two cores due to the influence of the electromagnetic field, which is caused by the measured current of the conductive wire, is detected as a voltage signal to detect the DC component. Also, the AC component is detected through the separate core or the separate circuit configuration.

Then, a magnetic flux is applied with a compensating current corresponding to the detected component, so that the compensating current is converged so as to offset a magnetic flux owing to the measured current, and then, the measured current is measured through the measurement of the converged compensating current.

However, in the current measuring device of the flux gate type according to the conventional techniques, the configuration for generating the oscillation signal of the sine wave or the square wave is formed separately from the coil wound around the cores, so that the oscillation signal according to the configuration thereof is simultaneously applied to both cores.

As a result, the time constant varies according to the magnetic characteristics of the core. Thus, when the oscillation signal of a fixed frequency, in that the magnetic characteristic of the core is not reflected, is applied, so that the core is incompletely magnetized, thereby deteriorating the accuracy of current measurement.

In order to solve such problem, it is necessary to generate the oscillation signal fit for the magnetic characteristics of the core. However, since the deviation of the error ratio of the core is large in the fabrication of the current measuring device, it is very difficult to adjust the circuit element of generating the oscillation signal to the core. Also, it is also very troublesome to adjust the circuit element to the produced measuring instruments one by one, resulting in a problem of deterioration of the productivity and performance thereof.

Furthermore, in the conventional techniques, after the coils are connected in series (in parallel when it sees from a connection point connecting for input of the oscillation signal) in order that the polarities of both cores are opposite to each other, the oscillation signal is applied to the series connection points of both coils, so that both cores are magnetized in the directions opposite to each other. In this time, even if a slight magnetization error is generated in both cores, there is a problem that the measurement performance appears as a large deviation.

Meanwhile, in the conventional techniques, since both cores magnetized by the oscillation signal are also magnetized by the measured current flowing in the conductive wire, if the measured current is large, the core is saturated at the beginning of the measurement, so that it oscillates at a high frequency which is much larger than the frequency of the oscillation signal. Accordingly, it is impossible to detect the direct current component using the fluxgate method.

### Patent Literature

Patent Literature 1 KR 20-0283971 Y1 (Jul. 19, 2002)

Patent Literature 2 KR 10-2010-0001504 A (Jan. 6, 2010)

Patent Literature 3 KR 10-2004-0001535 A (Jan. 7, 2004)

### DISCLOSURE

### Technical Problem

### Accordingly, the present invention has been made in view of the above-mentioned problems.

It is an object of the present invention to provide a current detection device having a multi-layered PCB core structure, which can replace a coil of a conventional current detection device to make electrical properties constant and allow for mass production.

It is another object of the present invention to provide a current detection device capable of detecting direct current (DC) and alternating current (AC) by having a flux-gate type multi-layered PCB core structure.

### Technical Solution

According to one aspect of the present invention so as to accomplish these objects, there is provided to a current detection device having a multi-layered PCB core structure, including:

an upper coil pattern forming layer (100) made of a nonmagnetic material and having a plurality of coil patterns (120) connected alternately from top to bottom and vice versa through via holes (110);

through-hole layers (200) positioned beneath the upper coil pattern forming layer with a central core layer (300) interposed therebetween, the through-hole layers (200) being horizontal to both sides of the central core layer, each of the through-hole layers (200) having a plurality of equal-sized via holes (210) formed at positions of the via holes (110);

a central core layer (300) made of a core material and formed between the through-hole layers; and

a lower coil pattern forming layer (400) positioned beneath the through-hole layers and the central core layer and made of a nonmagnetic material, the lower coil pattern forming layer (400) having a plurality of coil patterns (420) connected alternately from top to bottom and vice versa through a plurality of via holes (410).

### Advantageous Effects

A current detection device having a multi-layered PCB core structure according to the present invention has the following effects.

It is possible to replace the coil of a conventional current detection device to make electrical properties constant and allow for mass production by providing the current detection device having a multi-layered PCB core structure.

Therefore, it is possible to make the characteristics of ZCT and CT uniform.

In addition, by providing the current detection device having a flux-gate type multi-layered PCB core structure to detect DC and AC, it is possible to replace a conventional coiled flux-gate type device and allow for uniform quality and mass production without mechanical error using printing technique.

### BRIEF DESCRIPTION OF DRAWINGS

The above and other objects, features and advantages of the present invention will be more apparent from the following detailed description taken in conjunction with the accompanying drawings, in which:

FIG. 1 is a block diagram of a conventional current detection device;

FIG. 2 is a perspective view illustrating a current detection device having a multi-layered PCB core structure, the layers of which are stacked, according to a first embodiment of the present invention;

FIG. 3 is a stacked exemplary view;

FIG. 4 is a perspective view illustrating a current detection device having a multi-layered PCB core structure, the layers of which are stacked, according to a second embodiment of the present invention;

FIG. 5 is a stacked exemplary view;

FIGS. 6 and 7 are top views illustrating a state in which the layers of the current detection device having a multi-layered PCB core structure according to the second embodiment of the present invention are stacked;

FIG. 8 is a perspective view illustrating a square current detection device having a multi-layered PCB core structure according to the second embodiment of the present invention;

FIG. 9 is a perspective view illustrating a triangular current detection device; and

FIG. 10 is a perspective view illustrating a cut region in a square detection device.

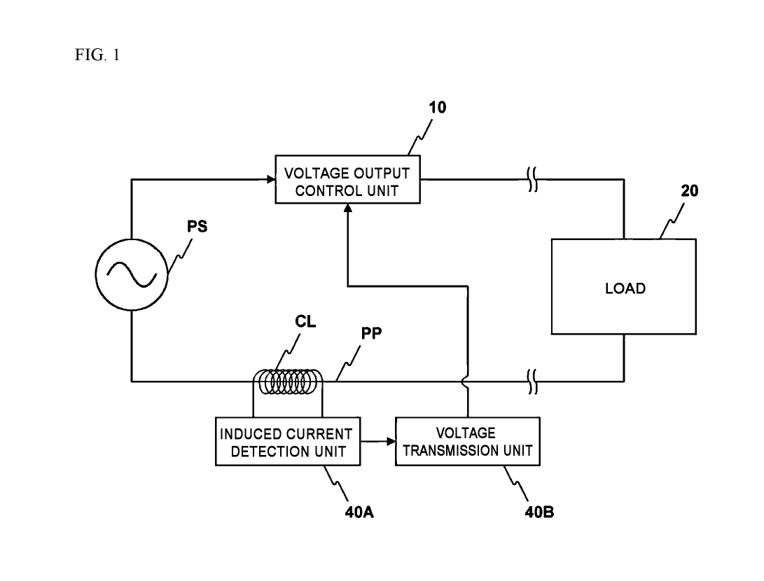

### REFERENCE SIGNS LIST

100: upper coil pattern forming layer
200: through-hole layers
300: central core layer
400: lower coil pattern forming layer
500: uppermost outer coil pattern forming layer
600: lowermost outer coil pattern forming layer

### Best Mode

### Mode for Invention

Hereinafter, a current detection device having a multi-layered PCB core structure according to embodiments of the present invention will be described in detail.

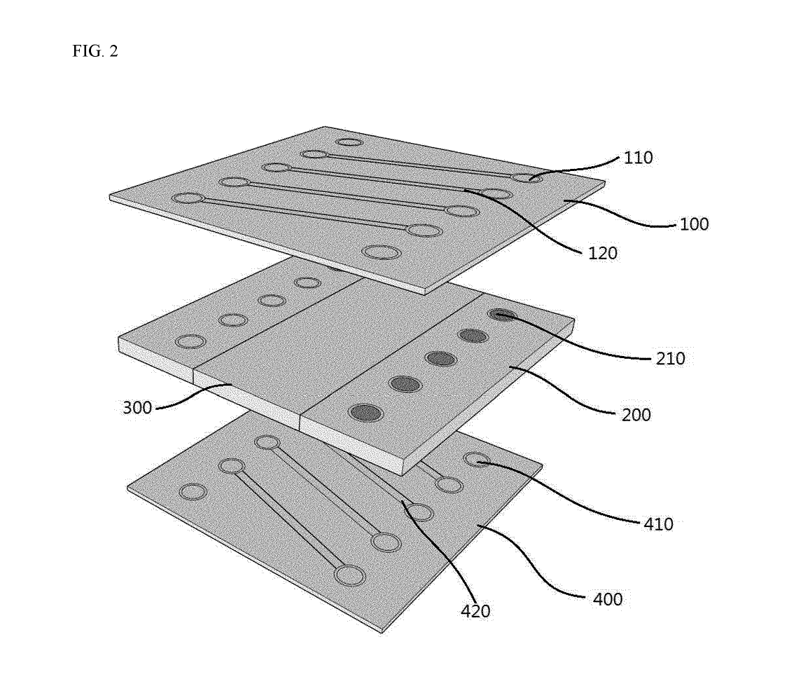

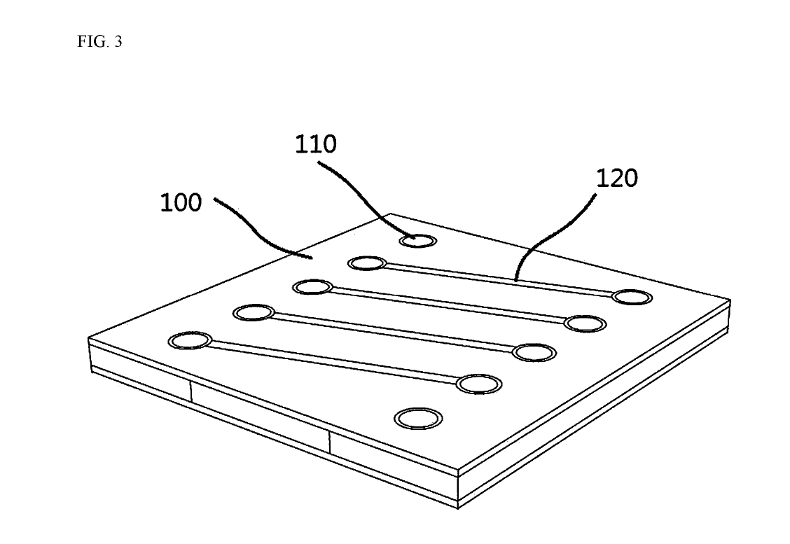

FIG. 2 is a perspective view illustrating a current detection device having a multi-layered PCB core structure, the layers of which are stacked, according to a first embodiment of the present invention. FIG. 3 is a stacked exemplary view.

As illustrated in FIGS. 2 and 3, the current detection device having a multi-layered PCB core structure includes, from the top, an upper coil pattern forming layer (100), through-hole layers (200), a central core layer (300) formed on the same horizontal line as the through-hole layers, and a lower coil pattern forming layer (400).

The upper coil pattern foiling layer (100) is made of a nonmagnetic material and has a plurality of coil patterns (120) connected alternately from top to bottom and vice versa through via holes (110).

The through-hole layers (200) are positioned beneath the upper coil pattern forming layer with the central core layer interposed therebetween, and are horizontal to both sides of the central core layer.

In this case, each of the through-hole layers (200) has a plurality of equal-sized via holes 210 when viewed perpendicular to the via holes (110).

The central core layer (300) is made of a core material and is formed between the through-hole layers.

The lower coil pattern forming layer (400) is positioned beneath the through-hole layers and the central core layer, and is made of a nonmagnetic material.

The lower coil pattern forming layer (400) has a plurality of coil patterns (420) connected alternately from top to bottom and vice versa through a plurality of via holes (410).

Through the above configuration, the coil patterns of the upper coil pattern forming layer (100) are connected to the via holes formed in the through-hole layers (200) and the via holes formed in the lower coil pattern forming layer (400) to provide a coil pattern formed in the lower portion thereof and a three-dimensional coil shape.

Meanwhile, the nonmagnetic material described in the present invention uses a Ni—Fe permalloy.

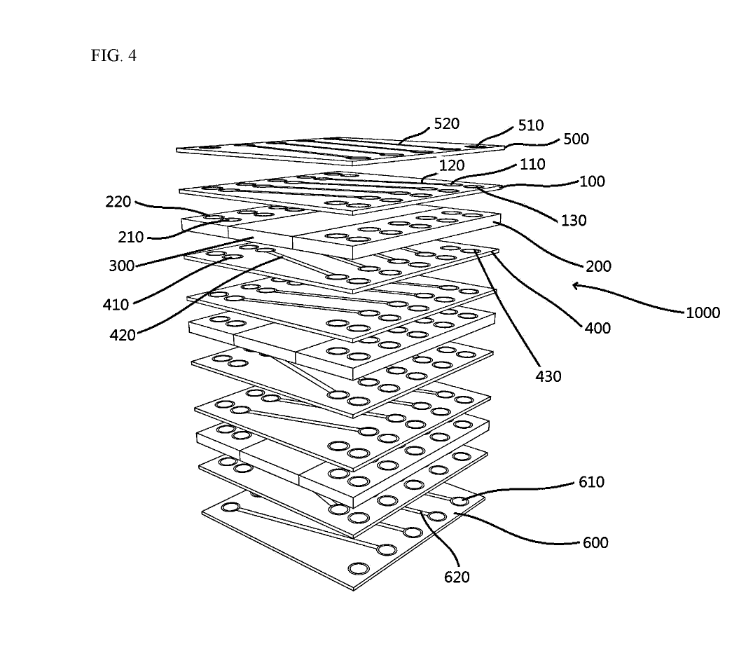

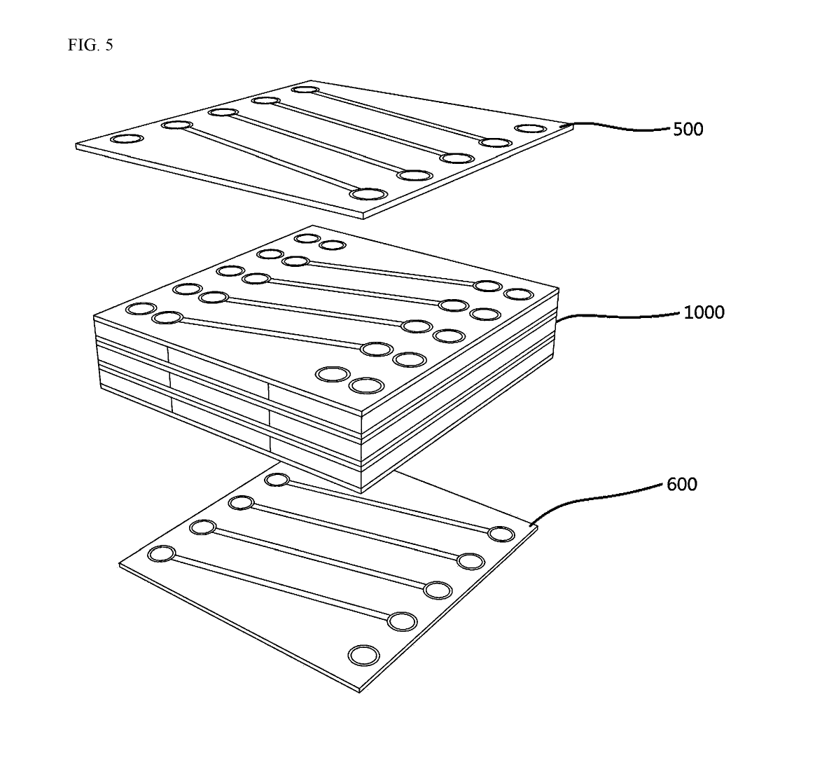

FIG. 4 is a perspective view illustrating a current detection device having a multi-layered PCB core structure, the layers of which are stacked, according to a second embodiment of the present invention. FIG. 5 is a stacked exemplary view.

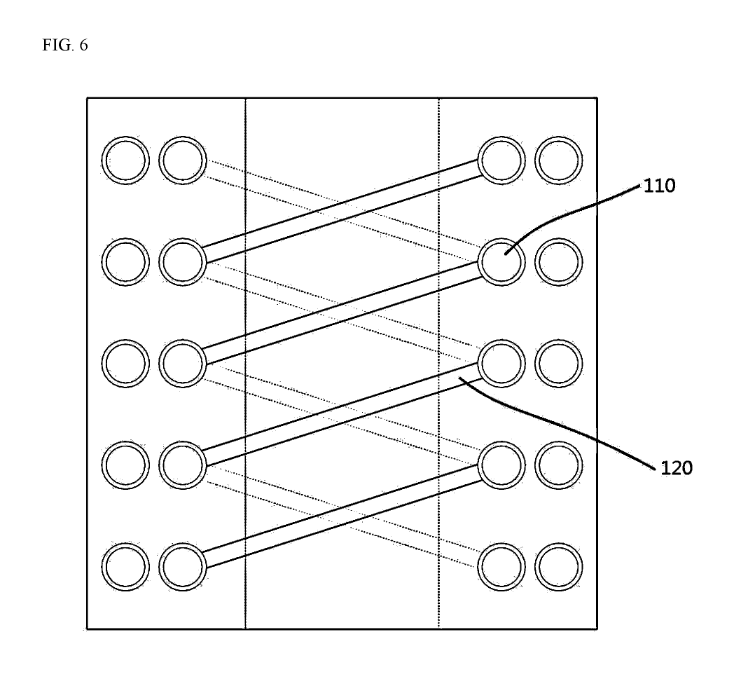

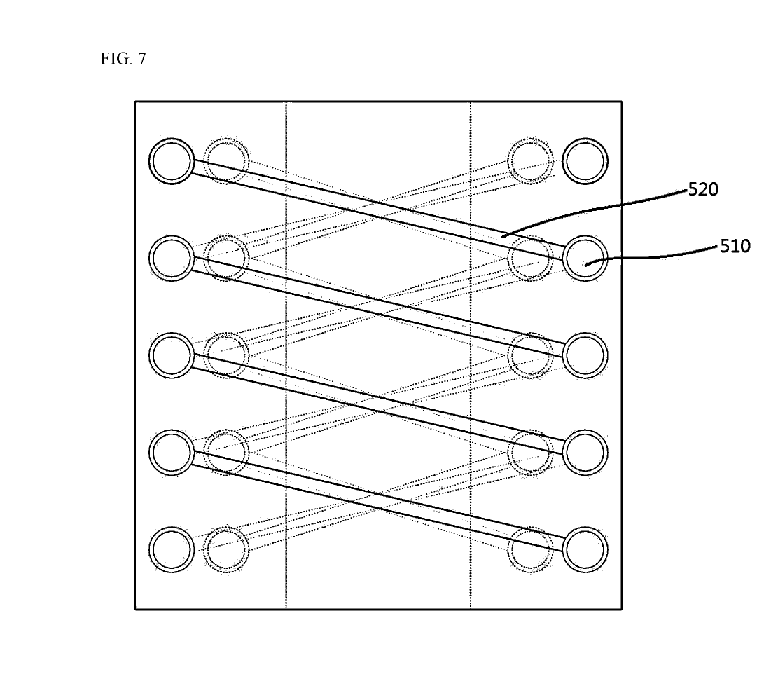

FIGS. 6 and 7 are top views illustrating a state in which the layers of the current detection device having a multi-layered PCB core structure according to the second embodiment of the present invention are stacked.

As illustrated in FIGS. 4 to 7, the current detection device having a multi-layered PCB core structure according to the second embodiment includes an uppermost outer coil pattern forming layer (500), an inner core section (1000), which includes an upper coil pattern forming layer (100), through-hole layers (200), a central core layer (300), and a lower coil pattern forming layer (400), and a lowermost outer coil pattern forming layer (600).

The inner core section (1000) is formed between the uppermost outer coil pattern forming layer (500) and the lowermost outer coil pattern forming layer (600).

In more detail, the uppermost outer coil pattern forming layer (500) is made of a nonmagnetic material and has a plurality of outer coil patterns (520) connected alternately from top to bottom and vice versa through outer via holes (510).

The lowermost outer coil pattern forming layer (600) is also made of a nonmagnetic material and is positioned beneath the inner core section.

In addition, the lowermost outer coil pattern forming layer (600) has a plurality of outer coil patterns (620) connected alternately from top to bottom and vice versa through outer via holes (610).

In this case, the inner core section includes the upper coil pattern forming layer (100), the through-hole layers (200), the central core layer (300), and the lower coil pattern forming layer (400), as in the first embodiment. However, the second embodiment differs from the first embodiment in that the outer via holes of the inner core section are vertically formed at the same position to connect the outer via holes formed in the uppermost outer coil pattern forming layer (500) to the outer via holes formed in the lowermost outer coil pattern forming layer (600).

Specifically, the upper coil pattern forming layer (100) is positioned beneath the uppermost outer coil pattern forming layer and has a plurality of coil patterns (120) connected alternately from top to bottom and vice versa through via holes (110). In addition, the upper coil pattern forming layer (100) has a plurality of equal-sized outer via holes 130 formed at the vertical positions of the outer via holes in the uppermost outer coil pattern forming layer.

The through-hole layers (200) are positioned beneath the upper coil pattern forming layer with the central core layer interposed therebetween, and are horizontal to both sides of the central core layer. In addition, each of the through-hole layers (200) has a plurality of equal-sized via holes (210) and outer via holes (220) formed at the vertical positions of the via holes (110) and the outer via holes (130), respectively.

The lower coil pattern forming layer (400) is positioned beneath the through-hole layers and the central core layer, is made of a nonmagnetic material, and has a plurality of coil patterns (420) connected alternately from top to bottom and vice versa through a plurality of via holes (410). In addition, the lower coil pattern forming layer (400) has a plurality of equal-sized outer via holes 430 formed at the vertical positions of the outer via holes (130).

In this case, at least two of the inner core sections are stacked in order to perform flux-gate type DC and AC detection functions in the current detection device having a multi-layered PCB core structure.

Therefore, the current detection device can detect DC and AC since it has a flux-gate type multi-layered PCB core structure.

Meanwhile, according to an additional aspect, the stacked-structured current detection device of the present invention is characterized by having one of circular, triangular, square, and polygonal shapes while having a central through-hole formed in the center thereof such that electric wires may pass through the central through-hole.

That is, since the current detection device must have a shape for penetrating electric wires to perform the operation of the current detection device, it may have a circular, triangular, square, or polygonal shape that has a central through-hole formed in the center thereof such that the electric wires may pass through the central through-hole.

The polygonal shape may be of any shape as long as it has a central through-hole formed in the center thereof, such as a diamond shape, a hexagonal shape, or an octagonal shape, and the current detection device will fall in the scope of the present invention even though it has any shape allowing for pass of electric wires.

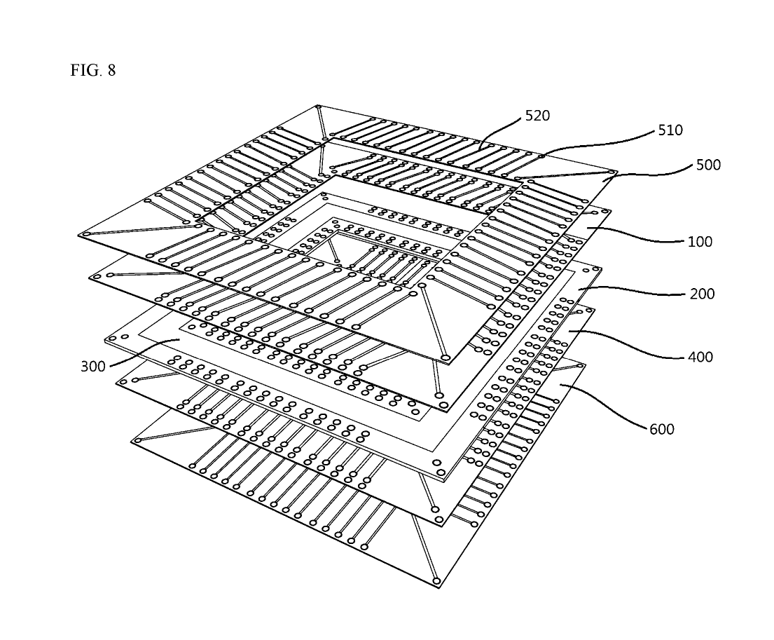

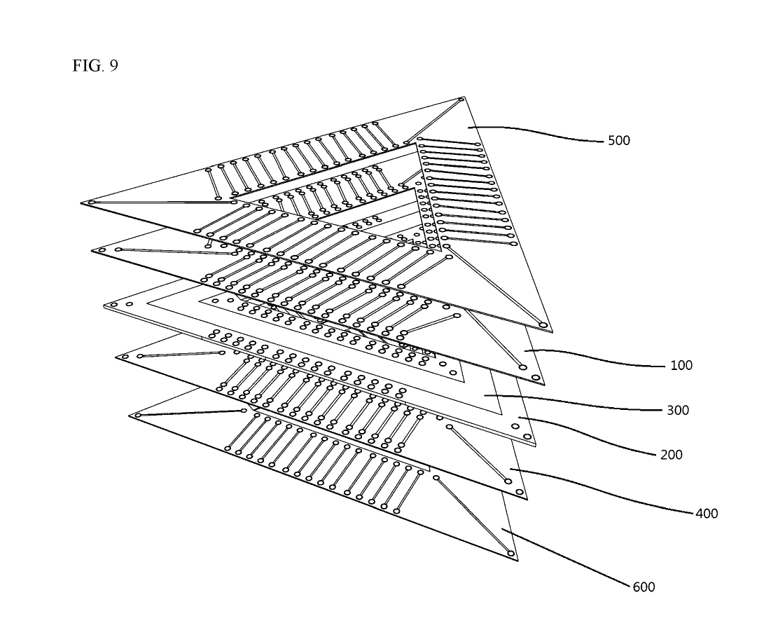

FIG. 8 is a perspective view illustrating a square current detection device having a multi-layered PCB core structure according to the second embodiment of the present invention. FIG. 9 is a perspective view illustrating a triangular current detection device.

FIGS. 2 to 6 are views illustrating a cut portion of one side of FIG. 8. The current detection device has a central through-hole formed in the center thereof to detect a current, and has a square shape that is formed with a central through-hole as in FIG. 8 or a triangular shape that is formed with a central through-hole as in FIG. 9.

Since coils are wound by a winding machine in the conventional coiled current detection device, the characteristics of the device are inevitably changed due to irregular distances, cross generation, or the like.

On the other hand, since patterns are formed and maintained at regular distances as illustrated in FIG. 8 in the present invention, the patterns have a shape, in which coils are wound, as a whole. Therefore, it is possible to provide uniform characteristics during mass production.

That is, when the coils are wound by a winding machine or manual operation, the distance between the coils may not be regular or the coils may be joined. In particular, it is difficult to keep the distance between the coils regular in case that the detection device has a shape other than a circular shape.

For example, only a circular detection device is available in the case of using a winding machine. However, since the distance between coils is inevitably irregular in an elliptical, angular-cornered square or triangular detection device, or the like, it is impossible to provide uniform characteristics.

Moreover, as the industrial structure develops day by day, the structure of industrial machinery changes to various forms.

For example, for the current detection device constituted in a solar inverter, circular shape is not suitable.

However, the present invention exhibits effects of applying various shapes to any industrial machinery structure and of making the bonding with existing industrial machinery structures excellent without increasing manufacturing costs.

That is, the present invention exhibits effects of providing an ultra-miniature detection device while providing uniform quality since there are no human intervention and no mechanical error, and of providing various types of detection devices.

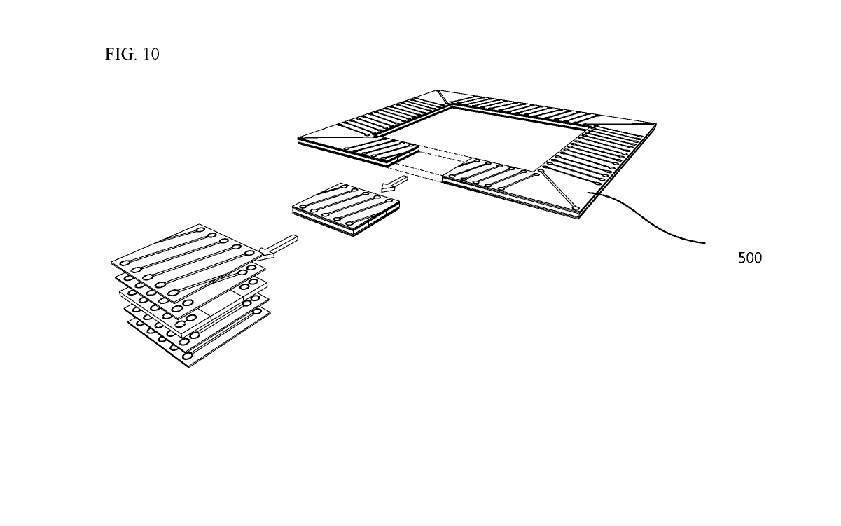

Meanwhile, FIG. 10 is a perspective view illustrating a cut region in a square detection device and an exploded perspective view of the cut region, which is specifically illustrated in FIGS. 2 to 7.

According to the above configuration of the present invention, it is possible to replace the coil of the conventional current detection device to make electrical properties constant and allow for mass production by providing the current detection device having the multi-layered PCB core structure.

Therefore, it is possible to make the characteristics of ZCT and CT uniform.

While the present invention has been described with respect to the specific embodiments, it will be apparent to those skilled in the art that various changes and modifications may be made without departing from the spirit and scope of the present invention as defined in the following claims.

### INDUSTRIAL APPLICABILITY

The current detection device having the multi-layered PCB core structure according to the present invention has the effects in that the coil of the conventional current detection device is replaceable to make electrical properties constant (uniform) and mass production is possible. Therefore, it can be useful in the field of a current detection.

1. A current detection device having a multi-layered PCB core structure, comprising:
an upper coil pattern forming layer (100) made of a nonmagnetic material and having a plurality of coil patterns (120) connected alternately from top to bottom and vice versa through via holes (110);
through-hole layers (200) positioned beneath the upper coil pattern forming layer with a central core layer (300) interposed therebetween, the through-hole layers (200) being horizontal to both sides of the central core layer, each of the through-hole layers (200) having a plurality of equal-sized via holes (210) formed at positions of the via holes (110);
a central core layer (300) made of a core material and formed between the through-hole layers; and
a lower coil pattern forming layer (400) positioned beneath the through-hole layers and the central core layer and made of a nonmagnetic material, the lower coil pattern forming layer (400) having a plurality of coil patterns (420) connected alternately from top to bottom and vice versa through a plurality of via holes (410),
wherein the current detection device has one of circular, triangular, square, and polygonal shapes while having a central through-hole formed in the center thereof such that electric wires passes through the central through-hole.

2. A current detection device having a multi-layered PCB core structure, comprising:
an uppermost outer coil pattern forming layer (500) made of a nonmagnetic material and having a plurality of outer coil patterns (520) connected alternately from top to bottom and vice versa through outer via holes (510);
an inner core section (1000) comprising an upper coil pattern forming layer (100), through-hole layers (200), a central core layer (300), and a lower coil pattern forming layer (400), wherein the upper coil pattern forming layer (100) is made of a nonmagnetic material, is positioned beneath the uppermost outer coil pattern forming layer, has a plurality of coil patterns (120) connected alternately from top to bottom and vice versa through via holes (110), and has a plurality of equal-sized outer via holes (130) formed at positions of the outer via holes (510), the through-hole layers (200) are positioned beneath the upper coil pattern forming layer with the central core layer interposed therebetween, are horizontal to both sides of the central core layer, and each have a plurality of equal-sized via holes (210) and outer via holes (220) formed at positions of the via holes (110) and the outer via holes (130), respectively, the central core layer (300) is made of a core material and is formed between the through-hole layers, and the lower coil pattern forming layer (400) is positioned beneath the through-hole layers and the central core layer, is made of a nonmagnetic material, has a plurality of coil patterns (420) connected alternately from top to bottom and vice versa through a plurality of via holes (410), and has a plurality of equal-sized outer via holes (430) formed at positions of the outer via holes (130); and
a lowermost outer coil pattern forming layer (600) made of a nonmagnetic material and positioned beneath the inner core section, the lowermost outer coil pattern forming layer (600) having a plurality of outer coil patterns (620) connected alternately from top to bottom and vice versa through outer via holes (610).

3. The current detection device according to claim 2, wherein at least two of the inner core sections are stacked in order to perform flux-gate type direct current and alternating current detection.
